(19) United States
(12) Patent Application Publication
(10) Pub. No.: US 2025/0055256 A1
(43) Pub. Date: Feb. 13, 2025

(54) VCSEL CHIP STRUCTURE FOR QUICK TEST AND METHOD FOR FORMING THE SAME

(71) Applicant: Taiwan-Asia Semiconductor Corporation, Hsinchu City (TW)

(72) Inventor: Shang-Che LEE, Hsinchu City (TW)

(21) Appl. No.: 18/754,764

(22) Filed: Jun. 26, 2024

(30) Foreign Application Priority Data
Aug. 8, 2023 (TW) 112129761

(51) Int. Cl. H01S 5/183; H01S 5/02; H01S 5/34

(52) U.S. Cl. CPC H01S 5/183; H01S 5/0218; H01S 5/34

(57) ABSTRACT

A VCSEL chip structure for quick test and a method for forming the same are provided. The VCSEL chip structure has probing and emission regions divided by a first trench, and includes a substrate, an epitaxial layer, a cap layer, and first and second electrodes. The epitaxial layer is formed on a top surface of the substrate. The cap layer is formed on the epitaxial layer. The first electrode is formed on the cap layer and on a bottom and two sidewalls of the first trench. The second electrode is formed on a bottom surface of the substrate. The probing region has multiple second trenches which divide the probing region into multiple sub-regions. The epitaxial layer in the emission region has a first wet oxidation layer with an aperture. The epitaxial layer in each sub-region of the probing region has a second wet oxidation layer spanning the respective sub-region.

### CROSS-REFERENCES TO RELATED APPLICATIONS

This application claims priority to Taiwan Patent Application No. 112129761 filed on Aug. 8, 2023, which is hereby incorporated by reference in its entirety.

### BACKGROUND OF THE INVENTION

### Field of the Invention

The present invention relates to a vertical cavity surface emitting laser (VCSEL) chip structure, particularly a VCSEL chip structure for quick test.

### Descriptions of the Related Art

In recent years, VCSEL components have been widely used as light sources in consumer electronics.

In the complete process of a VCSEL chip, an insulating layer is required for the structure to avoid sidewall current leakage and to restrict the current path to prevent current from entering the active layer from the probing region, as shown in FIG. 1. FIG. 1 is a cross-sectional view of a conventional VCSEL chip structure 1. The VCSEL chip structure 1 includes a substrate 11, an epitaxial layer 12 (which includes an N-type epitaxial layer 12N, a multiple quantum well layer 12M and a P-type epitaxial layer 12P), a cap layer 13, an insulating layer 14, a first electrode 15 and a second electrode 16. The epitaxial layer 12 further includes a wet oxidation layer 121. The probing region R1 (left side of the dotted line) and the emission region R2 (right side of the dotted line) are divided by a trench 102. Due to the need to form the insulating layer 14, the complete process of a VCSEL chip typically takes several days, making it difficult to validate the newly developed epitaxy in a short time to provide subsequent development improvement and optimization.

In view of this, how to shorten the number of days of the VCSEL chip process to achieve a quick test of a VCSEL chip is an urgent issue for the industry to solve.

### SUMMARY OF THE INVENTION

The objective of the present invention is to provide a VCSEL chip structure for quick test. By the design of omitting the process of the insulating layer and adding a trench in the probing region, a wet oxidation layer with a target aperture is formed in the emission region, and at the same time, a complete wet oxidation layer can be formed in the probing region to prevent current from the probing region from entering into the active layer to affect electrical properties. Therefore, compared with the complete VCSEL chip process, the VCSEL chip manufacturing process of the present invention can be shortened by several days for allowing the validation of the newly developed epitaxy to be completed in the shortest possible time to facilitate subsequent development improvement and optimization.

To achieve the above objective, the present invention discloses a VCSEL chip structure for quick test. The VCSEL chip structure has a probing region and an emission region. The probing region and the emission region are divided by a first trench. The VCSEL chip structure includes a substrate, an epitaxial layer, a cap layer, a first electrode and a second electrode. The epitaxial layer is formed on a top surface of the substrate. The cap layer is formed on the epitaxial layer. The first electrode is formed on the cap layer and on a bottom and two sidewalls of the first trench. The second electrode is formed on a bottom surface of the substrate. The probing region has a plurality of second trenches, and the second trenches divide the probing region into a plurality of sub-regions. The epitaxial layer in the emission region has a first wet oxidation layer with an aperture. The epitaxial layer in each of the sub-regions of the probing region has a second wet oxidation layer spanning the respective sub-region.

In an embodiment, the substrate is a gallium arsenide (GaAs) substrate.

In an embodiment, the epitaxial layer includes an N-type epitaxial layer formed on the top surface of the substrate, a multiple quantum well layer formed on the N-type epitaxial layer, and a P-type epitaxial layer formed on the multiple quantum well layer. The first wet oxidation layer is formed in the P-type epitaxial layer of the emission region, and each of the second wet oxidation layers is formed in the P-type epitaxial layer of the respective sub-region of the probing region. The first wet oxidation layer and each of the second wet oxidation layers are formed simultaneously in a wet air oxidation process.

In an embodiment, the epitaxial layer is grown and formed by a metal-organic chemical vapor deposition method or a molecular beam epitaxy method using an III-V group semiconductor material or an II-VI group semiconductor material.

In an embodiment, the first trench and the second trenches are formed simultaneously in a wet etching process or a dry etching process.

In addition, the present invention further discloses a method for forming a VCSEL chip structure for quick test. The method includes: providing a substrate, forming an epitaxial layer on a top surface of the substrate, forming a cap layer on the epitaxial layer, forming a first trench to divide the VCSEL chip structure into a probing region and an emission region, and forming a plurality of second trenches to divide the probing region into a plurality of sub-regions, forming a first wet oxidation layer in the epitaxial layer of the emission region, and forming a second wet oxidation layer in the epitaxial layer of each of the sub-regions of the probing region, wherein the first wet oxidation layer has an aperture and the second wet oxidation layer of each of the sub-regions spans the respective sub-region, forming a first electrode on the cap layer and on a bottom and two sidewalls of the first trench, and forming a second electrode on a bottom surface of the substrate.

In an embodiment, the substrate is a gallium arsenide (GaAs) substrate.

In an embodiment, the step of forming the epitaxial layer includes: forming an N-type epitaxial layer on the top surface of the substrate, forming a multiple quantum well layer on the N-type epitaxial layer, and forming a P-type epitaxial layer on the multiple quantum well layer. The first wet oxidation layer is formed in the P-type epitaxial layer of the emission region, and each of the second wet oxidation layers is formed in the P-type epitaxial layer of the respective sub-region of the probing region. The first wet oxidation layer and each of the second wet oxidation layers are formed simultaneously in a wet air oxidation process.

In an embodiment, the epitaxial layer is grown and formed by a metal-organic chemical vapor deposition method or a molecular beam epitaxy method using an III-V group semiconductor material or an II-VI group semiconductor material.

In an embodiment, the first trench and the second trenches are formed simultaneously in a wet etching process or a dry etching process.

After referring to the drawings and the detailed description of embodiments described later, those of ordinary skill in the art can understand other objectives of the present invention, as well as the technical means and implementations of the present invention.

### BRIEF DESCRIPTION OF THE DRAWINGS

FIG. 1 is a schematic cross-sectional view of a conventional VCSEL chip structure;

FIG. 2 is a schematic cross-sectional view of the VCSEL chip structure according to an embodiment of the present invention;

FIG. 3 is a flowchart of a method for forming a VCSEL chip structure of FIG. 2; and

FIGS. 4A-4G are schematic structural views corresponding to the flowchart of FIG. 3.

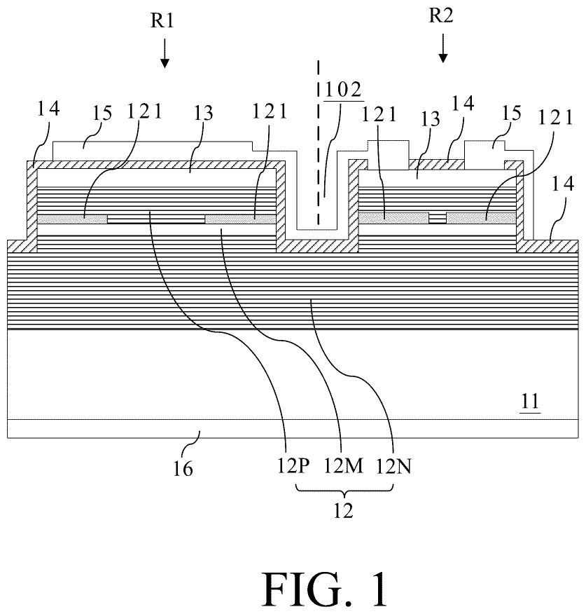

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, partial elements not directly related to the present invention are omitted from the illustration, and dimensional proportions among individual elements and the numbers of each element in the accompanying drawings are provided only for ease of understanding but are not intended to limit the actual scale.

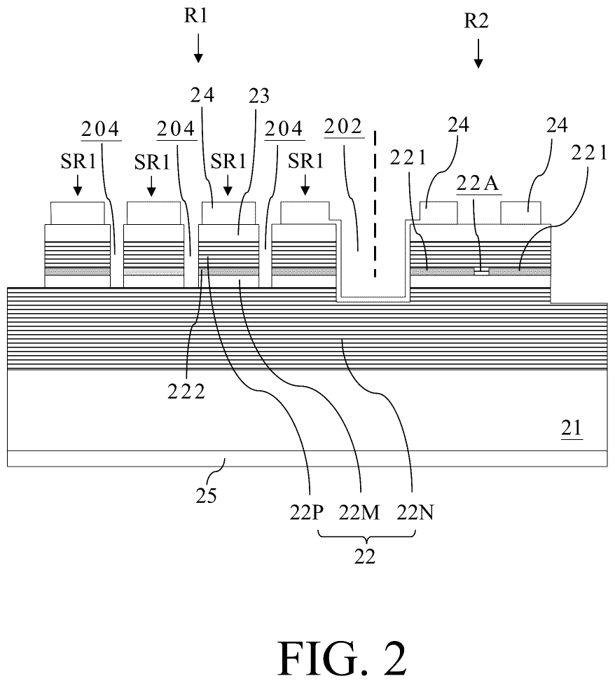

FIG. 2 shows the VCSEL chip structure 2 for quick test of the present invention. The VCSEL chip structure 2 has a probing region R1 and an emission region R2. The probing region R1 and the emission region R2 are divided by the first trench 202. The VCSEL chip structure 2 includes a substrate 21, an epitaxial layer 22, a cap layer 23, a first electrode 24 and a second electrode 25.

The substrate 21 may be a gallium arsenide (GaAs) substrate, but not limited thereto. The epitaxial layer 22 is formed on a top surface of the substrate 21. The epitaxial layer 22 may be grown and formed by a metal-organic chemical vapor deposition (MOCVD) method or a molecular beam epitaxy (MBE) method using an III-V group semiconductor material or an II-VI group semiconductor material. For example, the epitaxial layer 22 may be formed by stacking the alternating layers of gallium arsenide (GaAs), aluminum gallium arsenide (AlGaAs) and aluminum arsenide (AlAs). The energy gap of the epitaxial layer 22 may be between 1.3-2.5 eV.

The epitaxial layer 22 may include an N-type epitaxial layer 22N, a multiple quantum well layer 22M and a P-type epitaxial layer 22P. The N-type epitaxial layer 22N is formed on the top surface of the substrate 21. The multiple quantum well layer 22M is formed on the N-type epitaxial layer 22N. The P-type epitaxial layer 22P is formed on the multiple quantum well layer 22M.

The cap layer 23 is formed on the epitaxial layer 22. The first electrode 24 is formed on the cap layer 13 and on a bottom and two sidewalls of the first trench 202. The second electrode 25 is formed on a bottom surface of the substrate 21. The first electrode 24 is a P-electrode (P-pad), and the second electrode 25 is an N-electrode (N-pad). The first electrode 24 and the second electrode 25 are made of a metal material, such as gold (Au), titanium (Ti) or platinum (Pt).

The probing region R1 has a plurality of second trenches 204. The second trenches 204 divide the probing region R1 into a plurality of sub-regions SR1. The first trench 202 and the second trenches 204 are formed simultaneously in a wet etching process or a dry etching process. In other words, they are formed in the same etching process through a specific mask pattern.

The epitaxial layer 22 in the emission region R2 has a first wet oxidation layer 221 with an aperture 22A. The epitaxial layer 22 of each sub-region SR in the probing region R1 has a second wet oxidation layer 222 spanning the corresponding sub-region SR. In other words, as shown in FIG. 2, during the process, the present invention forms the first wet oxidation layer 221 with the aperture 22A in the emission region R2, and at the same time, also forms a complete second wet oxidation layer 222 in each sub-region SR1 of the probing region R1 to serve as an insulating layer that blocks current to prevent the probing region R1 from generating current that enters the active layer (i.e., the multiple quantum well layer 22M) and affects the electrical properties. Therefore, compared with the conventional complete process of a VCSEL chip, the VCSEL chip process of the present invention can be shortened by several days as the formation of the insulating layer can be omitted. This allows the validation of the newly developed epitaxy to be completed in the shortest possible time to facilitate subsequent development improvement and optimization.

Furthermore, as shown in FIG. 2, the first wet oxidation layer 221 is formed in the P-type epitaxial layer 22P in the emission region R2. Each second wet oxidation layer 222 is formed in the P-type epitaxial layer 22P of the corresponding sub-region SR1 of the probing region R1. The first wet oxidation layer 221 and the second wet oxidation layers 222 are formed simultaneously in a wet air oxidation process.

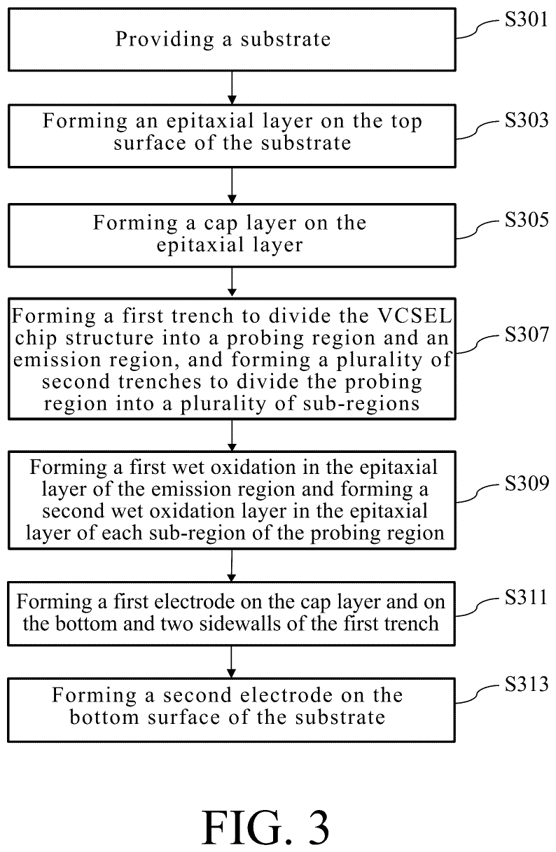

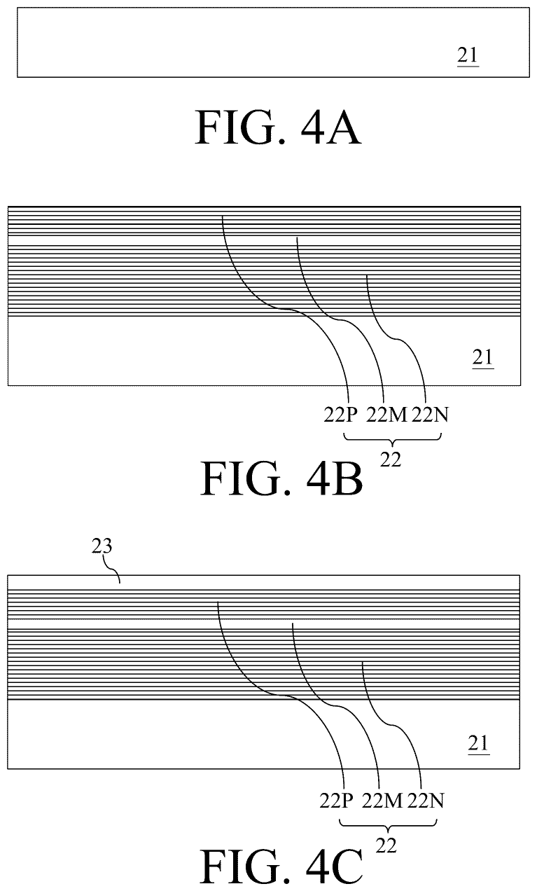

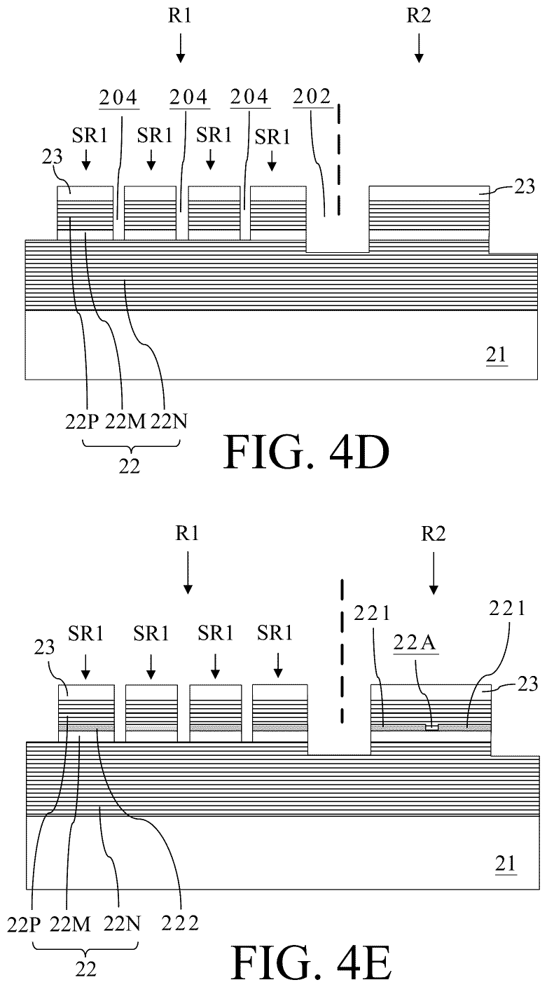

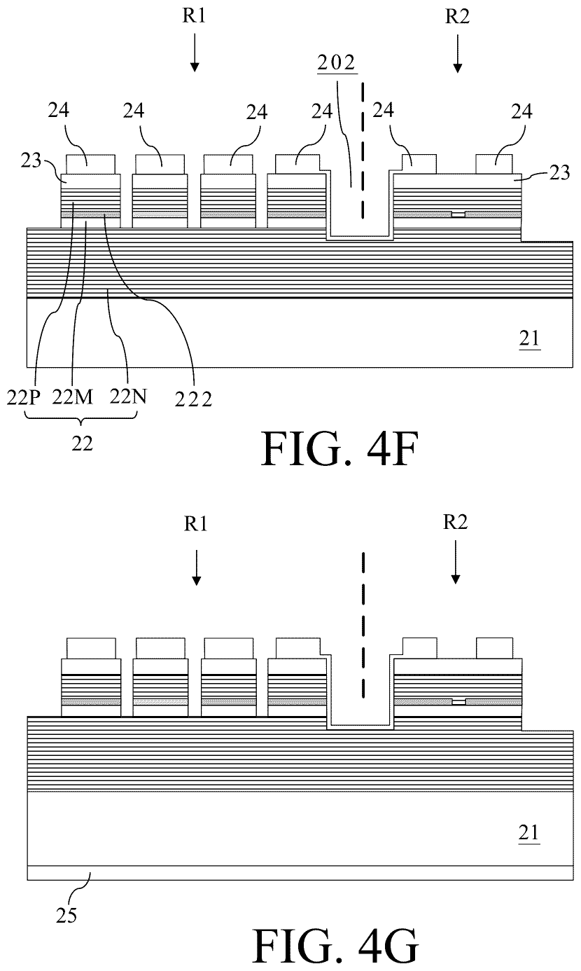

Please refer to FIG. 3 and FIG. 4A to FIG. 4G at the same time for the second embodiment of the present invention. FIG. 3 is the flowchart of the method for forming the VCSEL chip structure 2 for quick test. FIGS. 4A-4G are schematic structural views corresponding to the flowchart of FIG. 3.

First, in step S301, a substrate 21 is provided (as shown in FIG. 4A). Next, in step S303, an epitaxial layer 22 is formed on the top surface of the substrate 21 (as shown in FIG. 4B). In step S305, a cap layer 23 is formed on the epitaxial layer 22 (as shown in FIG. 4C).

Subsequently, in step S307, a first trench 202 is formed to divide the VCSEL chip structure 2 into a probing region R1 and an emission region R2, and a plurality of second trenches 204 are formed to divide the probing region R1 into a plurality of sub-regions SR1 (as shown in FIG. 4D).

Next, in step S309, a first wet oxidation layer 221 is formed in the epitaxial layer 22 of the emission region R2, and a second wet oxidation layer 222 is formed in the epitaxial layer 22 of each sub-region SR1 of the probing region R1 (shown in FIG. 4E).

In step S311, a first electrode 24 is formed on the cap layer 23 and on the bottom and two sidewalls of the first trench 202 (as shown in FIG. 4F). Then, in step S313, a second electrode 25 is formed on the bottom surface of the substrate 21 (as shown in FIG. 4G).

Furthermore, in step S303, the step of forming the epitaxial layer 22 includes: forming an N-type epitaxial layer 22N on the top surface of the substrate 21, forming a multiple quantum well layer 22M on the N-type epitaxial layer 22N, and forming a P-type epitaxial layer 22P on the multiple quantum well layer 22M. In addition, in step S309, the first wet oxidation layer 221 is formed in the P-type epitaxial layer 22P of the emission region R2, and each second wet oxidation layer 222 is formed in the P-type epitaxial layer 22P of the corresponding sub-region SR1 of the probing region R1.

It should be noted that the order of the steps of the flowchart illustrated in FIG. 3 is provided for illustrative purposes only and is not intended to limit the scope of the present invention. In other words, based on the disclosure of FIG. 3, a person having ordinary skill in the art can understand that any possible changes can be made to the order of the steps depicted therein, and these changes can still form the VCSEL chip structure depicted in FIG. 2.

In summary, the present invention provides a VCSEL chip structure for quick test by omitting the process of forming insulating layers. Therefore, compared with the conventional complete VCSEL chip process, the VCSEL chip manufacturing process of the present invention can be shortened by several days for allowing the validation of the newly developed epitaxy to be completed in the shortest possible time to facilitate subsequent development improvement and optimization.

The above embodiments are used only to illustrate the implementations of the present invention and to explain the technical features of the present invention, and are not intended to limit the scope of the present invention. Any modifications or equivalent arrangements that can be easily accomplished by people skilled in this art are considered to fall within the scope of the present invention, and the scope of the present invention should be limited by the claims of the patent application.

What is claimed is:

1. A VCSEL chip structure for quick test, the VCSEL chip structure comprising:
a probing region;
an emission region;
a first trench, the probing region and the emission region divided by the first trench;
a substrate;
an epitaxial layer formed on a top surface of the substrate;
a cap layer formed on the epitaxial layer;
a first electrode formed on the cap layer and on a bottom and two sidewalls of the first trench; and
a second electrode formed on a bottom surface of the substrate;
wherein the probing region has a plurality of second trenches, and the second trenches divide the probing region into a plurality of sub-regions;
wherein the epitaxial layer in the emission region has a first wet oxidation layer with an aperture;
wherein the epitaxial layer in each of the sub-regions of the probing region has a second wet oxidation layer spanning the respective sub-region.

2. The VCSEL chip structure of claim 1, wherein the substrate is a gallium arsenide (GaAs) substrate.

3. The VCSEL chip structure of claim 1, wherein the epitaxial layer comprises:
an N-type epitaxial layer formed on the top surface of the substrate;
a multiple quantum well layer formed on the N-type epitaxial layer; and
a P-type epitaxial layer formed on the multiple quantum well layer;
wherein the first wet oxidation layer is formed in the P-type epitaxial layer of the emission region, and each of the second wet oxidation layers is formed in the P-type epitaxial layer of the respective sub-region of the probing region;
wherein the first wet oxidation layer and each of the second wet oxidation layers are formed simultaneously in a wet air oxidation process.

4. The VCSEL chip structure of claim 1, wherein the epitaxial layer is grown and formed by a metal-organic chemical vapor deposition method or a molecular beam epitaxy method using an III-V group semiconductor material or an II-VI group semiconductor material.

5. The VCSEL chip structure of claim 1, wherein the first trench and the second trenches are formed simultaneously in a wet etching process or a dry etching process.

6. A method for forming a VCSEL chip structure for quick test, comprising:
providing a substrate;
forming an epitaxial layer on a top surface of the substrate;
forming a cap layer on the epitaxial layer;
forming a first trench to divide the VCSEL chip structure into a probing region and an emission region, and forming a plurality of second trenches to divide the probing region into a plurality of sub-regions;
forming a first wet oxidation layer in the epitaxial layer of the emission region, and forming a second wet oxidation layer in the epitaxial layer of each of the sub-regions of the probing region, wherein the first wet oxidation layer has an aperture and the second wet oxidation layer of each of the sub-regions spans the respective sub-region;
forming a first electrode on the cap layer and on a bottom and two sidewalls of the first trench; and
forming a second electrode on a bottom surface of the substrate.

7. The method of claim 6, wherein the substrate is a gallium arsenide (GaAs) substrate.

8. The method of claim 6, wherein the step of forming the epitaxial layer comprises:
forming an N-type epitaxial layer on the top surface of the substrate;
forming a multiple quantum well layer on the N-type epitaxial layer; and
forming a P-type epitaxial layer on the multiple quantum well layer;
wherein the first wet oxidation layer is formed in the P-type epitaxial layer of the emission region, and each of the second wet oxidation layers is formed in the P-type epitaxial layer of the respective sub-region of the probing region;
wherein the first wet oxidation layer and each of the second wet oxidation layers are formed simultaneously in a wet air oxidation process.

9. The method of claim 6, wherein the epitaxial layer is grown and formed by a metal-organic chemical vapor deposition method or a molecular beam epitaxy method using an III-V group semiconductor material or an II-VI group semiconductor material.

10. The method of claim 6, wherein the first trench and the second trenches are formed simultaneously in a wet etching process or a dry etching process.
